(19) United States
(12) Patent Application Publication
(10) Pub. No.: US 2024/0055483 A1
(43) Pub. Date: Feb. 15, 2024

(54) SEMICONDUCTOR DEVICE

(71) Applicant: FUJI ELECTRIC CO., LTD., Kanagawa (JP)

(72) Inventors: Yuki KARAMOTO, Matsumoto-city (JP); Kaname MITSUZUKA, Matsumoto-city (JP)

(21) Appl. No.: 18/356,255

(22) Filed: Jul. 21, 2023

(30) Foreign Application Priority Data
Aug. 12, 2022 (JP) 2022-128976

(51) Int. Cl. H01L 29/08; H01L 27/06; H01L 29/06; H01L 29/10; H01L 29/861; H01L 29/739

(52) U.S. Cl. CPC H01L 29/0834; H01L 27/0664; H01L 29/0638; H01L 29/1095; H01L 29/8613; H01L 29/7397

(57) ABSTRACT

Provided is a semiconductor device including a buffer region of a first conductivity type, which is provided between a lower surface of a semiconductor substrate and a drift region, has three or more doping concentration peaks in a depth direction of the semiconductor substrate, and has a higher concentration than the drift region, in which the three or more doping concentration peaks include a deepest peak farthest from the lower surface of the semiconductor substrate and a second peak second closest to the lower surface of the semiconductor substrate, and a peak width of the second peak is 2 times or more of a peak width of the deepest peak in the depth direction.

The contents of the following patent application(s) are incorporated herein by reference:

NO. 2022-128976 filed in JP on Aug. 12, 2022

### BACKGROUND

### 1. Technical Field

The present invention relates to a semiconductor device.

### 2. Related Art

There is known a semiconductor device provided with a buffer region (or a field stopper layer) having a plurality of doping concentration peaks on a lower surface of a semiconductor substrate (see, for example, Patent Documents 1 and 2).

### LIST OF CITED REFERENCES

### Patent Documents

Patent Document 1: US 2015/0214347

Patent Document 2: WO 2018/135448

### BRIEF DESCRIPTION OF THE DRAWINGS

FIG. 1 illustrates a top view showing an example of a semiconductor device 100 according to one embodiment of the present invention.

FIG. 2 illustrates an enlarged view of a region D in FIG. 1.

FIG. 3 illustrates a view showing an example of a cross section e-e in FIG. 2.

FIG. 4 illustrates a view showing an example of a doping concentration distribution 300 on a line f-f of FIG. 3.

FIG. 5 illustrates a view showing a doping concentration distribution in the vicinity of a doping concentration peak 210-2.

FIG. 6 illustrates a view showing another example of the doping concentration distribution in the vicinity of the doping concentration peak 210-2.

FIG. 7 illustrates a view showing a doping concentration distribution of a doping concentration peak 310-2 according to a comparative example.

FIG. 8 shows a voltage waveform and a current waveform during turn-off of a semiconductor device according to an example and a comparative example.

FIG. 9 illustrates a view showing a distribution example of an electric field intensity E1 during turn-off.

FIG. 10 illustrates a view showing another example of the doping concentration distribution of the doping concentration peak 210-2.

FIG. 11 illustrates a view for describing depth positions of a concave portion 218 and a kink portion 216.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solution of the invention.

As used herein, one side in a direction parallel to a depth direction of a semiconductor substrate is referred to as “upper” and the other side is referred to as “lower”. One surface of two principal surfaces of a substrate, a layer, or other member is referred to as an upper surface, and the other surface is referred to as a lower surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate a height direction with respect to the ground. Note that a +Z axis direction and a −Z axis direction are directions opposite to each other. When the Z axis direction is described without describing the signs, it means that the direction is parallel to the +Z axis and the −Z axis.

In the present specification, orthogonal axes parallel to an upper surface and lower surface of a semiconductor substrate are referred to as the X axis and the Y axis. Further, an axis perpendicular to the upper surface and the lower surface of the semiconductor substrate is referred to as the Z axis. In the present specification, the direction of the Z axis may be referred to as the depth direction. Further, in the present specification, a direction parallel to the upper surface and the lower surface of the semiconductor substrate may be referred to as a horizontal direction, including the X axis direction and the Y axis direction.

A region from a center of the semiconductor substrate in the depth direction to the upper surface of the semiconductor substrate may be referred to as an upper surface side. Similarly, the region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of a doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type, or a semiconductor presenting a conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking polarities of charges into account. As an example, when the donor concentration is N_{D} and the acceptor concentration is N_{A}, the net doping concentration at any position is given as N_{D}-N_{A}. In the present specification, the net doping concentration may be simply referred to as the doping concentration.

The donor has a function of supplying electrons to a semiconductor. The acceptor has a function of receiving electrons from the semiconductor. The donor and acceptor are not limited to the impurities themselves. For example, a VOH defect which is a combination of a vacancy (V), oxygen (O), and hydrogen (H) existing in the semiconductor functions as the donor that supplies electrons. The hydrogen donor may be a donor obtained by the combination of at least a vacancy (V) and hydrogen (H). Alternatively, interstitial Si—H which is a combination of interstitial silicon (Si-i) and hydrogen in a silicon semiconductor also functions as the donor that supplies electrons. In the present specification, the VOH defect or interstitial Si—H may be referred to as a hydrogen donor.

In the present specification, bulk donors of the N type are distributed throughout the semiconductor substrate. The bulk donor is a dopant donor substantially uniformly contained in an ingot during the manufacture of the ingot from which the semiconductor substrate is made. The bulk donor of this example is an element other than hydrogen. The dopant of the bulk donor is, for example, phosphorus, antimony, arsenic, selenium, or sulfur, but the present invention is not limited to these. The bulk donor of this example is phosphorus. The bulk donor is also contained in the P type region. The semiconductor substrate may be a wafer cut out from a semiconductor ingot, or may be a chip obtained by singulating the wafer. The semiconductor ingot may be manufactured by any of a Chokralski method (CZ method), a magnetic field applied Chokralski method (MCZ method), or a float zone method (FZ method). The ingot of this example is manufactured by the MCZ method. An oxygen concentration contained in the substrate manufactured by the MCZ method is 1×10¹⁷ to 7×10¹⁷/cm³. The oxygen concentration contained in the substrate manufactured by the FZ method is 1×10¹⁵ to 5×10¹⁶/cm³. When the oxygen concentration is high, hydrogen donors tend to be easily generated. A chemical concentration of a bulk donor distributed throughout the semiconductor substrate may be used for the bulk donor concentration, which may also be a value from 90% to 100% of the chemical concentration. Further, as the semiconductor substrate, a non-doped substrate not containing a dopant such as phosphorus may be used. In that case, the bulk donor concentration (DO) of the non-doped substrate is, for example, 1×10¹⁰/cm³ or more and 5×10¹²/cm³ or less. The bulk donor concentration (DO) of the non-doped substrate is preferably 1×10¹¹/cm³ or more. The bulk donor concentration (DO) of the non-doped substrate is preferably 5×10¹²/cm³ or less. Note that each concentration in the present invention may be a value at room temperature. As the value at room temperature, a value at 300 K (Kelvin) (about 26.9° C.) may be used as an example.

In the present specification, a description of a P+ type or an N+ type means a higher doping concentration than that of the P type or the N type, and a description of a P− type or an N− type means a lower doping concentration than that of the P type or the N type. Further, in the present specification, a description of a P++ type or an N++ type means a higher doping concentration than that of the P+ type or the N+ type. In the present specification, a unit system is the SI base unit system unless otherwise stated in particular. Although a unit of length may be expressed in cm, calculations may be carried out after conversion to meters (m).

A chemical concentration in the present specification indicates an atomic density of an impurity measured regardless of an electrical activation state. The chemical concentration can be measured by, for example, secondary ion mass spectrometry (SIMS). The net doping concentration described above can be measured by capacitance-voltage profiling (CV profiling). Furthermore, a carrier concentration measured by a spreading resistance profiling method (SRP method) may be set as the net doping concentration. The carrier concentration measured by the CV profiling or the SRP method may be set as a value in a thermal equilibrium state. Furthermore, in a region of an N type, the donor concentration is sufficiently higher than the acceptor concentration, and therefore, the carrier concentration in the region may be set as the donor concentration. Similarly, in a region of a P type, the carrier concentration in the region may be set as the acceptor concentration. In the present specification, the doping concentration of the N type region may be referred to as the donor concentration, and the doping concentration of the P type region may be referred to as the acceptor concentration.

When a concentration distribution of the donor, acceptor, or net doping has a peak in a region, a value of the peak may be set as the concentration of the donor, acceptor, or net doping in the region. In a case where the concentration of the donor, acceptor, or net doping is substantially uniform in a region, or the like, an average value of the concentration of the donor, acceptor, or net doping in the region may be set as the concentration of the donor, acceptor, or net doping. In the present specification, atoms/cm³ or/cm³ is used to indicate a concentration per unit volume. This unit is used for a concentration of a donor or an acceptor in a semiconductor substrate, or a chemical concentration. A notation of atoms may be omitted.

The carrier concentration measured by the SRP method may be lower than the concentration of the donor or the acceptor. In a range where a current flows when a spreading resistance is measured, the carrier mobility of the semiconductor substrate may be lower than a value in a crystalline state. The reduction in carrier mobility occurs when carriers are scattered due to disorder (disorder) of a crystal structure due to a lattice defect or the like.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorus or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen.

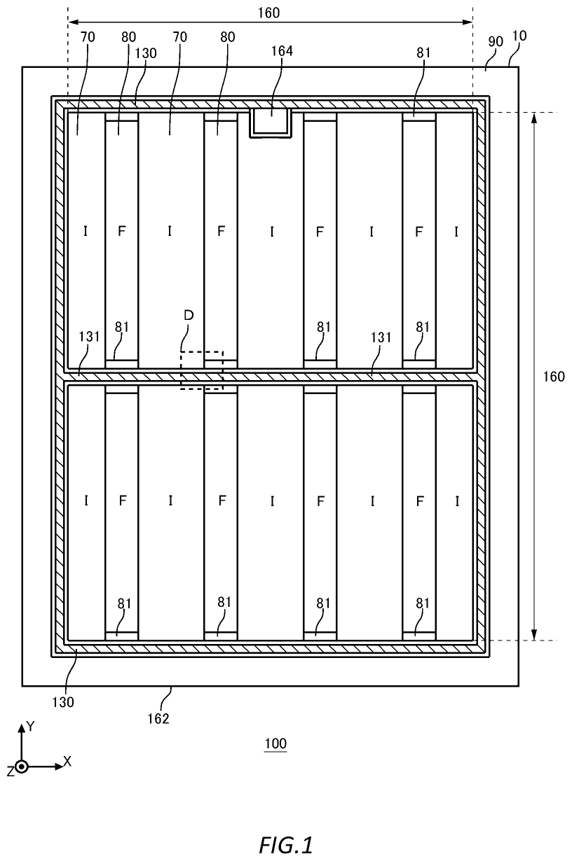

FIG. 1 illustrates a top view showing an example of a semiconductor device 100 according to one embodiment of the present invention. FIG. 1 shows a position at which each member is projected on an upper surface of a semiconductor substrate 10. FIG. 1 shows merely some members of the semiconductor device 100, and omits illustrations of some members.

The semiconductor device 100 includes the semiconductor substrate 10. The semiconductor substrate 10 is a substrate that is formed of a semiconductor material. As an example, the semiconductor substrate 10 is a silicon substrate. The semiconductor substrate 10 has an end side 162 in the top view. When merely referred to as the top view in the present specification, it means that the semiconductor substrate 10 is viewed from an upper surface side. The semiconductor substrate 10 of this example has two sets of end sides 162 opposite to each other in the top view. In FIG. 1, the X axis and the Y axis are parallel to any of the end sides 162. In addition, the Z axis is perpendicular to the upper surface of the semiconductor substrate 10.

The semiconductor substrate 10 is provided with an active portion 160. The active portion 160 is a region where a main current flows in the depth direction between the upper surface and a lower surface of the semiconductor substrate 10 when the semiconductor device 100 operates. An emitter electrode is provided above the active portion 160, but is omitted in FIG. 1. The active portion 160 may refer to a region that overlaps with the emitter electrode in the top view. Further, a region sandwiched by the active portion 160 in the top view may also be included in the active portion 160.

The active portion 160 is provided with at least one of a transistor portion 70 including a transistor element such as an insulated gate bipolar transistor (IGBT) or a diode portion 80 including a diode element such as a freewheeling diode (FWD). In the example of FIG. 1, the transistor portion 70 and the diode portion 80 are alternately arranged along a predetermined array direction (the X axis direction in this example) on the upper surface of the semiconductor substrate 10. The semiconductor device 100 of this example is a reverse-conducting IGBT (RC-IGBT).

In FIG. 1, a region where each of the transistor portions 70 is arranged is indicated by a symbol “I”, and a region where each of the diode portions 80 is arranged is indicated by a symbol F. In the present specification, a direction perpendicular to the array direction in the top view may be referred to as an extending direction (the Y axis direction in FIG. 1). Each of the transistor portions 70 and the diode portions 80 may have a longitudinal length in the extending direction. In other words, the length of each of the transistor portions 70 in the Y axis direction is larger than the width in the X axis direction. Similarly, the length of each of the diode portions 80 in the Y axis direction is larger than the width in the X axis direction. The extending direction of the transistor portion 70 and the diode portion 80, and the longitudinal direction of each trench portion described below may be the same.

Each of the diode portions 80 includes a cathode region of the N+ type in a region in contact with the lower surface of the semiconductor substrate 10. In the present specification, a region where the cathode region is provided is referred to as the diode portion 80. In other words, the diode portion 80 is a region that overlaps with the cathode region in the top view. On the lower surface of the semiconductor substrate 10, a collector region of the P+ type may be provided in a region other than the cathode region. In the present specification, the diode portion 80 may also include an extension region 81 where the diode portion 80 extends to a gate runner described below in the Y axis direction. The collector region is provided on a lower surface of the extension region 81.

The transistor portion 70 has the collector region of the P+ type in a region in contact with the lower surface of the semiconductor substrate 10. Further, in the transistor portion 70, an emitter region of the N type, a base region of the P type, and a gate structure having a gate conductive portion and a gate dielectric film are periodically arranged on the upper surface side of the semiconductor substrate 10.

The semiconductor device 100 may have one or more pads above the semiconductor substrate 10. The semiconductor device 100 of this example has a gate pad 164. The semiconductor device 100 may have a pad such as an anode pad, a cathode pad, and a current detection pad. Each pad is arranged in a region close to the end side 162. The region close to the end side 162 refers to a region between the end side 162 and the emitter electrode in the top view. When the semiconductor device 100 is mounted, each pad may be connected to an external circuit via a wiring such as a wire.

A gate potential is applied to the gate pad 164. The gate pad 164 is electrically connected to a conductive portion of a gate trench portion of the active portion 160. The semiconductor device 100 includes a gate runner that connects the gate pad 164 and the gate trench portion. In FIG. 1, the gate runner is hatched with diagonal lines.

The gate runner of this example includes an outer circumferential gate runner 130 and an active-side gate runner 131. The outer circumferential gate runner 130 is arranged between the active portion 160 and the end side 162 of the semiconductor substrate 10 in the top view. The outer circumferential gate runner 130 of this example encloses the active portion 160 in the top view. A region enclosed by the outer circumferential gate runner 130 in the top view may be the active portion 160. In addition, a well region is formed below the gate runner. The well region is a P type region having a higher concentration than the base region described below, and is formed to a position deeper than the base region from the upper surface of the semiconductor substrate 10. In the top view, the region enclosed by the well region may be the active portion 160.

The outer circumferential gate runner 130 is connected to the gate pad 164. The outer circumferential gate runner 130 is arranged above the semiconductor substrate 10. The outer circumferential gate runner 130 may be a metal wiring containing aluminum or the like.

The active-side gate runner 131 is provided in the active portion 160. Providing the active-side gate runner 131 in the active portion 160 can reduce a variation in wiring length from the gate pad 164 for each region of the semiconductor substrate 10.

The outer circumferential gate runner 130 and the active-side gate runner 131 are connected to the gate trench portion of the active portion 160. The outer circumferential gate runner 130 and the active-side gate runner 131 are arranged above the semiconductor substrate 10. The outer circumferential gate runner 130 and the active-side gate runner 131 may be a wiring formed of a semiconductor such as polysilicon doped with an impurity.

The active-side gate runner 131 may be connected to the outer circumferential gate runner 130. The active-side gate runner 131 of this example is provided extending in the X axis direction so as to cross the active portion 160 from one outer circumferential gate runner 130 to the other outer circumferential gate runner 130 sandwiching the active portion 160, substantially at the center of the Y axis direction. When the active portion 160 is divided by the active-side gate runner 131, the transistor portion 70 and the diode portion 80 may be alternately arranged in the X axis direction in each of the divided regions.

The semiconductor device 100 may include a temperature sensing portion (not shown) that is a PN junction diode formed of polysilicon or the like, and a current detection portion (not shown) that simulates an operation of the transistor portion provided in the active portion 160.

The semiconductor device 100 of this example includes an edge termination structure portion 90 between the active portion 160 and the end side 162 in the top view. The edge termination structure portion 90 of this example is arranged between the outer circumferential gate runner 130 and the end side 162. The edge termination structure portion 90 relaxes an electric field strength on the upper surface side of the semiconductor substrate 10. The edge termination structure portion 90 may include at least one of a guard ring, a field plate, or a RESURF annularly provided to enclose the active portion 160.

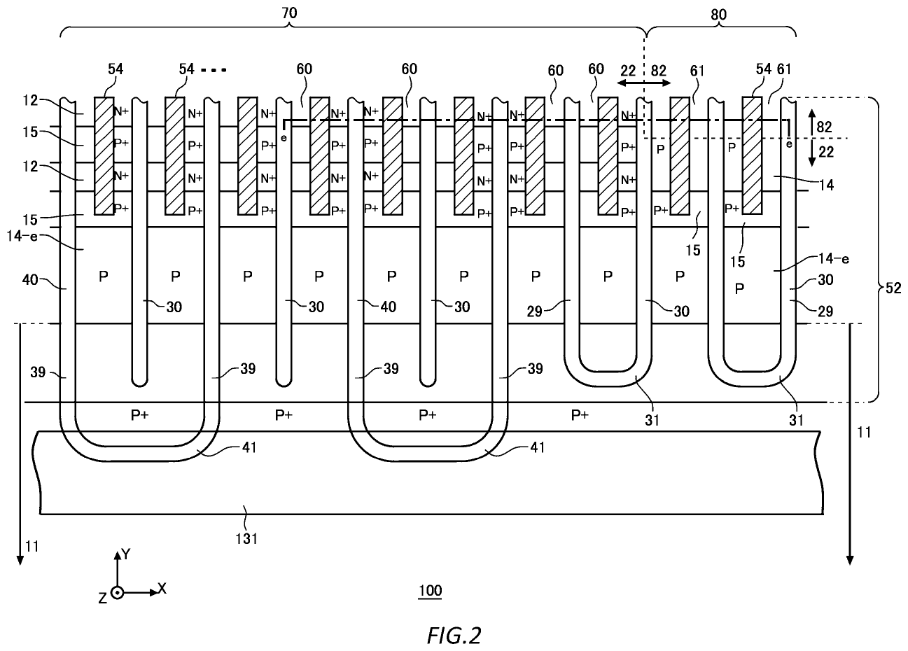

FIG. 2 illustrates an enlarged view of a region D in FIG. 1. The region D is a region including the transistor portion 70, the diode portion 80, and the active-side gate runner 131. The semiconductor device 100 of this example includes a gate trench portion 40, a dummy trench portion 30, a well region 11, an emitter region 12, a base region 14, and a contact region 15, which are provided inside the semiconductor substrate 10 on the upper surface side. The gate trench portion 40 and the dummy trench portion 30 each are an example of the trench portion. In addition, the semiconductor device 100 of this example includes an emitter electrode 52 and the active-side gate runner 131 which are provided above the upper surface of the semiconductor substrate 10. The emitter electrode 52 and the active-side gate runner 131 are provided separate from each other.

An interlayer dielectric film is provided between the emitter electrode 52 and the active-side gate runner 131, and the upper surface of the semiconductor substrate 10, but the interlayer dielectric film is omitted in FIG. 2. In the interlayer dielectric film of this example, a contact hole 54 is provided passing through the interlayer dielectric film. In FIG. 2, each contact hole 54 is hatched with the diagonal lines.

The emitter electrode 52 is provided above the gate trench portion 40, the dummy trench portion 30, the well region 11, the emitter region 12, the base region 14, and the contact region 15. The emitter electrode 52 is in contact with the emitter region 12, the contact region 15, and the base region 14 on the upper surface of the semiconductor substrate 10, through the contact hole 54. Further, the emitter electrode 52 is connected to a dummy conductive portion in the dummy trench portion 30 through the contact hole provided in the interlayer dielectric film. The emitter electrode 52 may be connected to the dummy conductive portion of the dummy trench portion 30 at an edge of the dummy trench portion 30 in the Y axis direction. The dummy conductive portion of the dummy trench portion 30 does not need to be connected to the emitter electrode 52 and the gate conductive portion, and may be controlled to be set at a potential different from the potential of the emitter electrode 52 and the potential of the gate conductive portion.

The active-side gate runner 131 is connected to the gate trench portion 40 through the contact hole provided in the interlayer dielectric film. The active-side gate runner 131 may be connected to a gate conductive portion of the gate trench portion 40 in an edge portion 41 of the gate trench portion 40 in the Y axis direction. The active-side gate runner 131 is not connected to the dummy conductive portion in the dummy trench portion 30.

The emitter electrode 52 is formed of a material including metal. FIG. 2 shows a range where the emitter electrode 52 is provided. For example, at least a part of a region of the emitter electrode 52 is formed of aluminum or an aluminum-silicon alloy, for example, a metal alloy such as AlSi and AlSiCu. The emitter electrode 52 may have a barrier metal formed of titanium, a titanium compound, or the like below a region formed of aluminum or the like. Further, a plug, which is formed by embedding tungsten or the like so as to be in contact with the barrier metal and aluminum or the like, may be included in the contact hole.

The well region 11 is provided so as to overlap with the active-side gate runner 131. The well region 11 is provided so as to extend with a predetermined width also in a range not overlapping with the active-side gate runner 131. The well region 11 of this example is provided away from an end of the contact hole 54 in the Y axis direction toward the active-side gate runner 131 side. The well region 11 is a region of a second conductivity type in which the doping concentration is higher than the base region 14. The base region 14 of this example is a P type, and the well region 11 is a P+ type.

Each of the transistor portion 70 and the diode portion 80 includes a plurality of trench portions arranged in the array direction. In the transistor portion 70 of this example, one or more gate trench portions 40 and one or more dummy trench portions 30 are alternately provided along the array direction. In the diode portion 80 of this example, the plurality of dummy trench portions 30 are provided along the array direction. In the diode portion 80 of this example, the gate trench portion 40 is not provided.

The gate trench portion 40 of this example may have two linear portions 39 extending along the extending direction perpendicular to the array direction (portions of a trench that are linear along the extending direction), and the edge portion 41 connecting the two linear portions 39. The extending direction in FIG. 2 is the Y axis direction.

At least a part of the edge portion 41 is preferably provided in a curved shape in a top view. By connecting end portions of the two linear portions 39 in the Y axis direction by the edge portion 41, it is possible to relax an electric field strength at the end portions of the linear portions 39.

In the transistor portion 70, the dummy trench portions 30 are provided between the respective linear portions 39 of the gate trench portions 40. Between the respective linear portions 39, one dummy trench portion 30 may be provided, or a plurality of dummy trench portions 30 may be provided. The dummy trench portion 30 may have a linear shape extending in the extending direction, or may have linear portions 29 and an edge portion 31 similar to the gate trench portion 40. The semiconductor device 100 shown in FIG. 2 includes both of the linear dummy trench portion 30 having no edge portion 31, and the dummy trench portion 30 having the edge portion 31.

A diffusion depth of the well region 11 may be deeper than the depth of the gate trench portion 40 and the dummy trench portion 30. The end portions of the gate trench portion 40 and the dummy trench portion 30 in the Y axis direction are provided in the well region 11 in a top view. In other words, the bottom of each trench portion in the depth direction is covered with the well region 11 at the end portion of each trench portion in the Y axis direction. With this configuration, the electric field strength at the bottom of each trench portion can be relaxed.

A mesa portion is provided between the respective trench portions in the array direction. The mesa portion refers to a region sandwiched between the trench portions inside the semiconductor substrate 10. As an example, an upper end of the mesa portion is the upper surface of the semiconductor substrate 10. The depth position of the lower end of the mesa portion is the same as the depth position of the lower end of the trench portion. The mesa portion of this example is provided extending in the extending direction (the Y axis direction) along the trench, on the upper surface of the semiconductor substrate 10. In this example, a mesa portion 60 is provided in the transistor portion 70, and a mesa portion 61 is provided in the diode portion 80. In the case of simply mentioning “mesa portion” in the present specification, the portion refers to each of the mesa portion 60 and the mesa portion 61.

Each mesa portion is provided with the base region 14. Of the base regions 14 exposed on the upper surface of the semiconductor substrate 10 in the mesa portion, a region arranged closest to the active-side gate runner 131 is assumed to be a base region 14-e. While FIG. 2 shows the base region 14-e arranged at one end portion of each mesa portion in the extending direction, the base region 14-e is also arranged at the other end portion of each mesa portion. In each mesa portion, at least one of the emitter region 12 of the first conductivity type or the contact region 15 of the second conductivity type may be provided in a region sandwiched between the base regions 14-e in a top view. The emitter region 12 of this example is an N+ type, and the contact region 15 is a P+ type. The emitter region 12 and the contact region 15 may be provided between the base region 14 and the upper surface of the semiconductor substrate 10 in the depth direction.

The mesa portion 60 of the transistor portion 70 has the emitter region 12 exposed on the upper surface of the semiconductor substrate 10. The emitter region 12 is provided in contact with the gate trench portion 40. The mesa portion 60 in contact with the gate trench portion 40 may be provided with the contact region 15 exposed on the upper surface of the semiconductor substrate 10.

Each of the contact region 15 and the emitter region 12 in the mesa portion 60 is provided from one trench portion to the other trench portion in the X axis direction. As an example, the contact region 15 and the emitter region 12 of the mesa portion 60 are alternately arranged along the extending direction of the trench portion (the Y axis direction).

In another example, the contact region 15 and the emitter region 12 of the mesa portion 60 may be provided in a stripe pattern along the extending direction of the trench portion (the Y axis direction). For example, the emitter region 12 is provided in a region in contact with the trench portion, and the contact region 15 is provided in a region sandwiched between the emitter regions 12.

The mesa portion 61 of the diode portion 80 is not provided with the emitter region 12. The base region 14 and the contact region 15 may be provided on an upper surface of the mesa portion 61. In the region sandwiched between the base regions 14-e on the upper surface of the mesa portion 61, the contact region 15 may be provided in contact with each base region 14-e. The base region 14 may be provided in a region sandwiched between the contact regions 15 on the upper surface of the mesa portion 61. The base region 14 may be arranged in the entire region sandwiched between the contact regions 15.

The contact hole 54 is provided above each mesa portion. The contact hole 54 is arranged in the region sandwiched between the base regions 14-e. The contact hole 54 of this example is provided above each region of the contact region 15, the base region 14, and the emitter region 12. The contact hole 54 is not provided in regions corresponding to the base region 14-e and the well region 11. The contact hole 54 may be arranged at the center of the mesa portion 60 in the array direction (the X axis direction).

In the diode portion 80, a cathode region 82 of the N+ type is provided in a region in direct contact with the lower surface of the semiconductor substrate 10. On the lower surface of the semiconductor substrate 10, a collector region 22 of the P+ type may be provided in a region where the cathode region 82 is not provided. The cathode region 82 and the collector region 22 are provided between the lower surface 23 of the semiconductor substrate 10 and a buffer region 20. In FIG. 2, a boundary between the cathode region 82 and the collector region 22 is indicated by a dotted line.

The cathode region 82 is arranged apart from the well region 11 in the Y axis direction. With this configuration, a distance between the P type region (the well region 11) which has a relatively high doping concentration and is formed up to a deep position and the cathode region 82 is ensured, so that the breakdown voltage can be improved. The end portion of the cathode region 82 of this example in the Y axis direction is arranged farther away from the well region 11 than the end portion of the contact hole 54 in the Y axis direction. In another example, the end portion of the cathode region 82 in the Y axis direction may be arranged between the well region 11 and the contact hole 54.

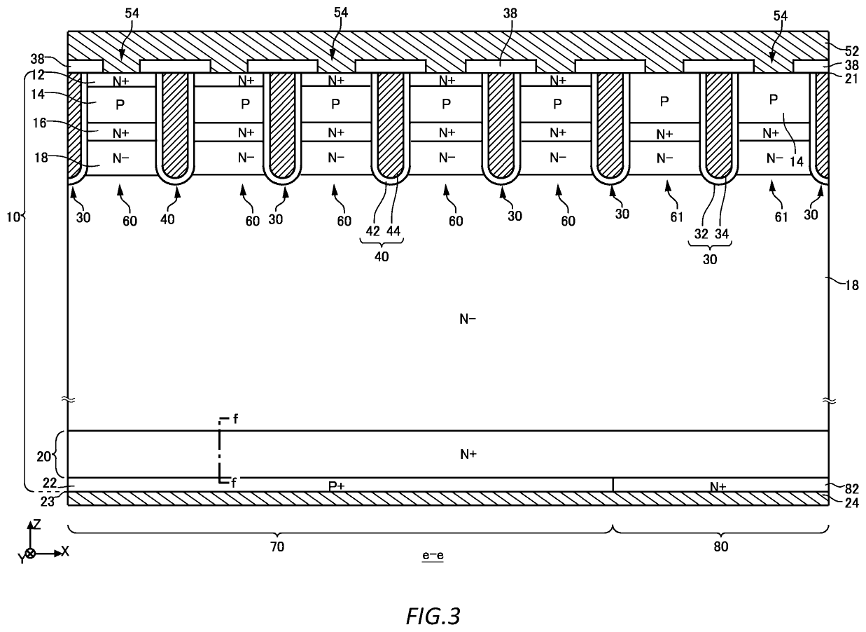

FIG. 3 illustrates a view showing an example of a cross section e-e in FIG. 2. The cross section e-e is an XZ plane passing through the emitter region 12 and the cathode region 82. The semiconductor device 100 of this example includes the semiconductor substrate 10, the interlayer dielectric film 38, the emitter electrode 52, and the collector electrode 24 in the cross section.

The interlayer dielectric film 38 is provided on the upper surface of the semiconductor substrate 10. The interlayer dielectric film 38 is a film including at least one layer of a dielectric film such as silicate glass to which an impurity such as boron or phosphorus is added, a thermal oxide film, and other dielectric films. The interlayer dielectric film 38 is provided with the contact hole 54 described in FIG. 2.

The emitter electrode 52 is provided above the interlayer dielectric film 38. The emitter electrode 52 is in contact with the upper surface 21 of the semiconductor substrate 10 through the contact hole 54 of the interlayer dielectric film 38. The collector electrode 24 is provided on the lower surface 23 of the semiconductor substrate 10. The emitter electrode 52 and the collector electrode 24 are formed of a metal material such as aluminum. In the present specification, the direction in which the emitter electrode 52 is connected to the collector electrode 24 (the Z axis direction) is referred to as the depth direction.

The semiconductor substrate 10 includes an N type or N− type drift region 18. The drift region 18 is provided in each of the transistor portion 70 and the diode portion 80.

In the mesa portion 60 of the transistor portion 70, the N+ type emitter region 12 and the P type base region 14 are provided in order from the upper surface 21 side of the semiconductor substrate 10. The drift region 18 is provided below the base region 14. The mesa portion 60 may be provided with an N+ type accumulation region 16. The accumulation region 16 is arranged between the base region 14 and the drift region 18.

The emitter region 12 is exposed on the upper surface 21 of the semiconductor substrate 10 and is provided in contact with the gate trench portion 40. The emitter region 12 may be in contact with the trench portions on both sides of the mesa portion 60. The emitter region 12 has a higher doping concentration than the drift region 18.

The base region 14 is provided below the emitter region 12. The base region 14 of this example is provided in contact with the emitter region 12. The base region 14 may be in contact with the trench portions on both sides of the mesa portion 60.

The accumulation region 16 is provided below the base region 14. The accumulation region 16 is an N+ type region having a higher doping concentration than the drift region 18. That is, the accumulation region 16 has a higher donor concentration than the drift region 18. By providing the accumulation region 16 having the high concentration between the drift region 18 and the base region 14, it is possible to improve a carrier injection enhancement effect (IE effect) and reduce an on-voltage. The accumulation region 16 may be provided to entirely cover a lower surface of the base region 14 in each mesa portion 60.

The mesa portion 61 of the diode portion 80 is provided with the P type base region 14 in contact with the upper surface 21 of the semiconductor substrate 10. The drift region 18 is provided below the base region 14. In the mesa portion 61, the accumulation region 16 may be provided below the base region 14.

In each of the transistor portion 70 and the diode portion 80, an N+ type buffer region 20 may be provided below the drift region 18. The doping concentration of the buffer region 20 is higher than the doping concentration of the drift region 18. The buffer region 20 may have a concentration peak having a higher doping concentration than the drift region 18. The doping concentration of the concentration peak refers to a doping concentration at a local maximum of the concentration peak. Further, as the doping concentration of the drift region 18, an average value of doping concentrations in a region where the doping concentration distribution is substantially flat may be used.

The buffer region 20 may have two or more concentration peaks in the depth direction (the Z axis direction) of the semiconductor substrate 10. The concentration peak of the buffer region 20 may be provided at the same depth position as, for example, a chemical concentration peak of hydrogen (proton) or phosphorus. The buffer region 20 may function as a field stopper layer which prevents a depletion layer expanding from the lower end of the base region 14 from reaching the collector region 22 of the P+ type and the cathode region 82 of the N+ type.

In the transistor portion 70, the collector region 22 of the P+ type is provided below the buffer region 20. An acceptor concentration of the collector region 22 is higher than an acceptor concentration of the base region 14. The collector region 22 may include an acceptor which is the same as or different from an acceptor of the base region 14. The acceptor of the collector region 22 is, for example, boron.

Below the buffer region 20 in the diode portion 80, the cathode region 82 of the N+ type is provided. A donor concentration of the cathode region 82 is higher than a donor concentration of the drift region 18. A donor of the cathode region 82 is, for example, hydrogen or phosphorus. Note that an element serving as a donor and an acceptor in each region is not limited to the example described above. The collector region 22 and the cathode region 82 are exposed on the lower surface 23 of the semiconductor substrate 10 and are connected to the collector electrode 24. The collector electrode 24 may be in contact with the entire lower surface 23 of the semiconductor substrate 10. The emitter electrode 52 and the collector electrode 24 are formed of a metal material such as aluminum.

One or more gate trench portions 40 and one or more dummy trench portions 30 are provided on the upper surface 21 side of the semiconductor substrate 10. Each trench portion passes through the base region 14 from the upper surface 21 of the semiconductor substrate 10, and is provided to below the base region 14. In a region where at least any of the emitter region 12, the contact region 15, or the accumulation region 16 is provided, each trench portion also passes through the doping regions of these. The configuration of the trench portion penetrating the doping region is not limited to the one manufactured in the order of forming the doping region and then forming the trench portion. The configuration of the trench portion penetrating the doping region also includes a configuration of the doping region being formed between the trench portions after forming the trench portion.

As described above, the transistor portion 70 is provided with the gate trench portion 40 and the dummy trench portion 30. In the diode portion 80, the dummy trench portion 30 is provided, and the gate trench portion 40 is not provided. The boundary in the X axis direction between the diode portion 80 and the transistor portion 70 in this example is the boundary between the cathode region 82 and the collector region 22.

The gate trench portion 40 includes a gate trench, a gate dielectric film 42, and a gate conductive portion 44 provided on the upper surface 21 of the semiconductor substrate 10. The gate dielectric film 42 is provided to cover the inner wall of the gate trench. The gate dielectric film 42 may be formed by oxidizing or nitriding a semiconductor on the inner wall of the gate trench. The gate conductive portion 44 is provided on an inner side of the gate dielectric film 42 inside the gate trench. That is, the gate dielectric film 42 insulates the gate conductive portion 44 from the semiconductor substrate 10. The gate conductive portion 44 is formed of a conductive material such as polysilicon.

The gate conductive portion 44 may be provided longer than the base region 14 in the depth direction. The gate trench portion 40 in the cross section is covered by the interlayer dielectric film 38 on the upper surface 21 of the semiconductor substrate 10. The gate conductive portion 44 is electrically connected to the gate runner. When a predetermined gate voltage is applied to the gate conductive portion 44, a channel is formed by an electron inversion layer in a surface layer of the base region 14 at a boundary in contact with the gate trench portion 40.

The dummy trench portions 30 may have the same structure as the gate trench portions 40 in the cross section. The dummy trench portion 30 includes a dummy trench, a dummy dielectric film 32, and a dummy conductive portion 34 provided on the upper surface 21 of the semiconductor substrate 10. The dummy conductive portion 34 is electrically connected to the emitter electrode 52. The dummy dielectric film 32 is provided to cover an inner wall of the dummy trench. The dummy conductive portion 34 is provided inside the dummy trench, and is provided on an inner side of the dummy dielectric film 32. The dummy dielectric film 32 insulates the dummy conductive portion 34 from the semiconductor substrate 10. The dummy conductive portion 34 may be formed of the same material as the gate conductive portion 44. For example, the dummy conductive portion 34 is formed of a conductive material such as polysilicon. The dummy conductive portion 34 may have the same length as the gate conductive portion 44 in the depth direction.

The gate trench portion 40 and the dummy trench portion 30 of this example are covered by the interlayer dielectric film 38 on the upper surface 21 of the semiconductor substrate 10. Note that the bottoms of the dummy trench portion 30 and the gate trench portion 40 may be formed in a curved-surface shape (a curved shape in the cross section) convexly downward.

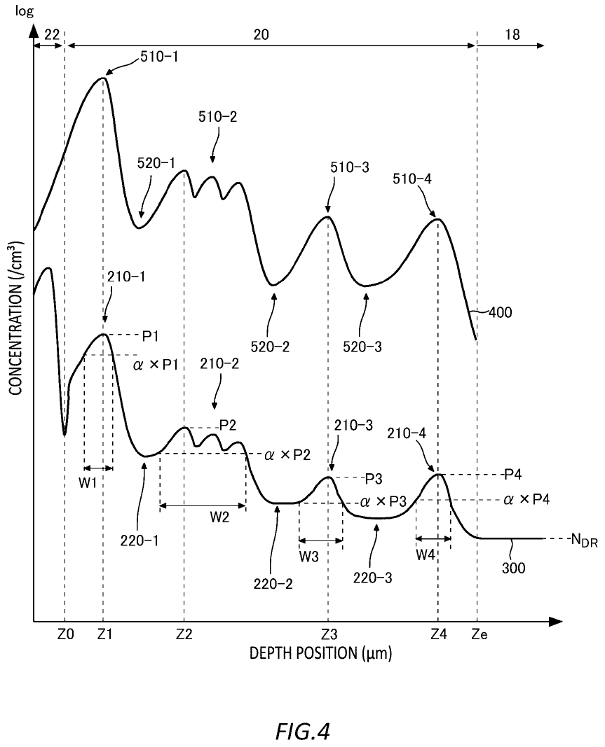

FIG. 4 illustrates a view showing an example of a doping concentration distribution 300 and a hydrogen chemical concentration distribution 400 on a line f-f in FIG. 3. The line f-f is a line that passes through the buffer region 20 and is parallel to the Z axis. The horizontal axis in FIG. 4 represents a depth position (a position in the Z axis direction) in the semiconductor substrate 10. In the present specification, unless otherwise stated, using the lower surface 23 of the semiconductor substrate 10 as a reference position in the Z axis direction, a distance from the lower surface 23 is given as a position in the Z axis direction.

The drift region 18 is provided above the buffer region 20. The doping concentration of the drift region 18 may be substantially constant. The doping concentration NDR of the drift region 18 may be the same as the bulk donor concentration. In another example, the doping concentration of the drift region 18 may be higher than the bulk donor concentration. A depth position of a boundary between the drift region 18 and the buffer region 20 is given as Ze. The depth position Ze is a depth position at which the doping concentration becomes NDR for the first time in a direction directed from the buffer region 20 toward the drift region 18.

The buffer region 20 is provided between the drift region 18 and the lower surface 23. The collector region 22 is provided between the buffer region 20 and the lower surface 23. The collector region 22 may have a doping concentration peak. The collector region 22 is in contact with the lower surface 23. A depth position of a boundary between the collector region 22 and the buffer region 20 is given as Z0. The depth position Z0 is a position of a PN junction formed by the collector region 22 and the buffer region 20.

The buffer region 20 has three or more doping concentration peaks 210 having a higher doping concentration than the drift region 18. In the example of FIG. 4, the number of doping concentration peaks 210 is four, but the number of doping concentration peaks 210 is not limited thereto. In this example, a doping concentration peak 210-1, a doping concentration peak 210-2, a doping concentration peak 210-3, and a doping concentration peak 210-4 are arranged in the order of proximity from the lower surface 23 of the semiconductor substrate 10. The doping concentration peak 210-1 closest to the lower surface 23 is an example of a first peak. The doping concentration peak 210-2 second closest to the lower surface 23 is an example of a second peak. The doping concentration peak 210-3 third closest to the lower surface 23 is an example of a third peak. Moreover, the doping concentration peak 210-3 whose distance from the lower surface 23 is second largest is also an example of a second deepest peak. The doping concentration peak 210-4 whose distance from the lower surface 23 is the largest is an example of a deepest peak. Further, one valley portion 220 is arranged between the respective doping concentration peaks 210. In other words, a valley portion 220-k at which the doping concentration shows a local minimum value is arranged between a doping concentration peak 210-k (note that k is an integer of 1 or more) and a doping concentration peak 210-(k+1) arranged adjacent to each other in the depth direction. The valley portion 220-1 is an example of a first valley portion closest to the lower surface 23 of the semiconductor substrate 10. The valley portion 220-3 is an example of a deepest valley portion closest to the upper surface 21 of the semiconductor substrate 10. The valley portion 220 may have a flat portion in which a portion where the doping concentration shows a local minimum value is continuous in the depth direction.

Maximum values of the doping concentrations of the doping concentration peak 210-1, the doping concentration peak 210-2, the doping concentration peak 210-3, and the doping concentration peak 210-4 are respectively given as P1, P2, P3, and P4, and peak widths thereof are respectively given as W1, W2, W3, and W4. Moreover, in each doping concentration peak 210-k, a depth position at which the doping concentration becomes a maximum value Pk is given as Zk. The peak width Wk of the doping concentration peak 210-k may be a length in the depth direction of the continuous portion where the doping concentration becomes α×Pk or more in the doping concentration peak 210-k. The continuous portion includes a depth position Zk at which the doping concentration becomes the maximum value Pk. A coefficient α may be 0.5, 0.3, 0.1, or a value smaller than 0.1. The coefficient α may be 0.01. When the coefficient α is 0.5, the peak width of the doping concentration peak 210-k is a full width at half maximum (FWHM) of the doping concentration peak 210-k. The coefficient α is common to the respective doping concentration peaks 210.

When the semiconductor device 100 (the transistor portion 70 in this example) is turned off, a space charge region (also referred to as a depletion layer) expands from a depth position of a PN junction on the upper surface 21 side (in this example, the PN junction formed by the base region 14 and the accumulation region 16) toward the lower surface 23 while a collector-emitter voltage Vce gradually increases. If the space charge region reaches the doping concentration peak 210 having a high concentration when the voltage Vce is close to a peak voltage, a voltage overshoot is easily caused in a time waveform of the collector-emitter voltage Vce.

For preventing the space charge region from reaching the collector region 22, the doping concentration peak 210-1 and the doping concentration peak 210-2 may be set to have relatively high concentrations. In addition, with a doping concentration distribution with which the space charge region reaches the doping concentration peak 210-1, the space charge region will highly likely reach the collector region 22. Thus, the doping concentration distribution may be designed such that the space charge region reaches the vicinity of the doping concentration peak 210-2 when the voltage Vce is at a peak voltage. However, if the doping concentration of the doping concentration peak 210-2 is high, a voltage overshoot in the collector-emitter voltage Vce during turn-off may become high.

The peak width W2 of the doping concentration peak 210-2 of this example is 2 times or more of the peak width W4 of the doping concentration peak 210-4. By setting the peak width W2 of the doping concentration peak 210-2 large, a maximum doping concentration P2 of the doping concentration peak 210-2 can be made small while maintaining an integrated value of the doping concentration in the doping concentration peak 210-2 in the depth direction. Thus, the voltage overshoot when the space charge region reaches the vicinity of the doping concentration peak 210-2 can be lowered. The peak width W2 may be 2.5 times or more or 3 times or more of the peak width W4.

For example, dopant ions are implanted at each of a plurality of depth positions in a depth range where the doping concentration peak 210-2 is to be formed. Accordingly, the peak width W2 of the doping concentration peak 210-2 becomes large. Further, while maintaining a total dose amount of the dopant ions with respect to the depth range, dose amounts of the dopant ions with respect to the respective depth positions can be made small, and the doping concentration P2 of the doping concentration peak 210-2 can be made small.

The peak width W2 of the doping concentration peak 210-2 may be 2 times or more, 2.5 times or more, or 3 times or more of the peak width W3 of the doping concentration peak 210-3. The peak width W2 of the doping concentration peak 210-2 may be 2 times or more, 2.5 times or more, or 3 times or more of the peak width W1 of the doping concentration peak 210-1. The peak width W2 of the doping concentration peak 210-2 may be larger than a value obtained by adding the peak width W4 of the doping concentration peak 210-4 and the peak width W3 of the doping concentration peak 210-3.

The doping concentration P2 of the doping concentration peak 210-2 may be smaller than the doping concentration P1 of the doping concentration peak 210-1. The doping concentration P2 may be 1/10 or less, 1/50 or less, or 1/100 or less of the doping concentration P1.

The doping concentration P2 of the doping concentration peak 210-2 may be larger than the doping concentration P3 of the doping concentration peak 210-3. The doping concentration P2 may be 2 times or more or 5 times or more of the doping concentration P3. The doping concentration P2 may be 50 times or less or 10 times or less of the doping concentration P3. The doping concentration P2 of the doping concentration peak 210-2 may be equal to or smaller than, or smaller than 1×10¹⁵/cm³, or may be 5×10¹⁴/cm³ or less.

The doping concentration P2 of the doping concentration peak 210-2 may be larger than the doping concentration P4 of the doping concentration peak 210-4. The doping concentration P2 may be 2 times or more or 5 times or more of the doping concentration P4. The doping concentration P2 may be 50 times or less or 10 times or less of the doping concentration P4.

As an example, a relationship of the doping concentrations may be P1 >P2 >P3 and P2 >P4. P3 >P4, P3<P4, or P3=P4 may also be established.

When the buffer region 20 is formed by a hydrogen donor, the buffer region 20 may have a hydrogen chemical concentration distribution 400. The hydrogen chemical concentration distribution 400 may have a hydrogen chemical concentration peak 510-k corresponding to the doping concentration peak 210-k. The hydrogen chemical concentration distribution 400 may have a valley portion 520-k of the hydrogen chemical concentration corresponding to the valley portion 220-k of the doping concentration.

A depth position of the hydrogen chemical concentration peak 510-k may match with the depth position Zk of the doping concentration peak 210-k while including an error of 10% or less. In the present specification, the depth position of the concentration peak is a position at which the concentration peak shows a local maximum value (that is, a position of a local maximum). When a flat portion in which a portion showing a local maximum value is continuous in the depth direction exists in the concentration peak, the depth position of the concentration peak is a center position of the flat portion in the depth direction. In the present specification, an error in the depth position refers to an error in the distance (μm) from the lower surface 23. A local maximum of the doping concentration peak 210-k may be arranged within a depth range of the full width at half maximum of the hydrogen chemical concentration peak 510-k, and a local maximum of the hydrogen chemical concentration peak 510-k may be arranged within a depth range of the full width at half maximum of the doping concentration peak 210-k.

The hydrogen chemical concentration peak 510-1 may correspond to the doping concentration peak 210-1. The depth position of the hydrogen chemical concentration peak 510-1 may match with the depth position Z1 of the doping concentration peak 210-1 while including an error of 10% or less. A local maximum of the doping concentration peak 210-1 may be arranged within a depth range of the full width at half maximum of the hydrogen chemical concentration peak 510-1, and a local maximum of the hydrogen chemical concentration peak 510-1 may be arranged within a depth range of the full width at half maximum of the doping concentration peak 210-1.

The hydrogen chemical concentration peak 510-2 may correspond to the doping concentration peak 210-2. The depth position of the hydrogen chemical concentration peak 510-2 may match with the depth position Z2 of the doping concentration peak 210-2 while including an error of 10% or less. A local maximum of the doping concentration peak 210-2 may be arranged within a depth range of the full width at half maximum of the hydrogen chemical concentration peak 510-2, and a local maximum of the hydrogen chemical concentration peak 510-2 may be arranged within a depth range of the full width at half maximum of the doping concentration peak 210-2.

The hydrogen chemical concentration peak 510-3 may correspond to the doping concentration peak 210-3. The depth position of the hydrogen chemical concentration peak 510-3 may match with the depth position Z3 of the doping concentration peak 210-3 while including an error of 10% or less. A local maximum of the doping concentration peak 210-3 may be arranged within a depth range of the full width at half maximum of the hydrogen chemical concentration peak 510-3, and a local maximum of the hydrogen chemical concentration peak 510-3 may be arranged within a depth range of the full width at half maximum of the doping concentration peak 210-3.

The hydrogen chemical concentration peak 510-4 may correspond to the doping concentration peak 210-4. The depth position of the hydrogen chemical concentration peak 510-4 may match with the depth position Z4 of the doping concentration peak 210-4 while including an error of 10% or less. A local maximum of the doping concentration peak 210-4 may be arranged within a depth range of the full width at half maximum of the hydrogen chemical concentration peak 510-4, and a local maximum of the hydrogen chemical concentration peak 510-4 may be arranged within a depth range of the full width at half maximum of the doping concentration peak 210-4.

The depth position of the valley portion 520-k of the hydrogen chemical concentration may match with the depth position of the valley portion 220-k of the doping concentration while including an error of 10% or less. In the present specification, the depth position of the valley portion is a position at which the valley portion shows a local minimum value. When a flat portion in which a portion showing a local minimum value is continuous in the depth direction exists in the valley portion, the depth position of the valley portion is a center position of the flat portion in the depth direction. The valley portion 220-k may be arranged within a depth range where the hydrogen chemical concentration becomes 2 times or less of the local minimum value in the valley portion 520-k, and the valley portion 520-k may be arranged within a depth range where the doping concentration becomes 2 times or less of the local minimum value in the valley portion 220-k.

The valley portion 520-1 of the hydrogen chemical concentration may correspond to the valley portion 220-1 of the doping concentration. The depth position of the valley portion 520-1 may match with the depth position of the valley portion 220-1 while including an error of 10% or less. The valley portion 220-1 may be arranged within a depth range where the hydrogen chemical concentration becomes 2 times or less of the local minimum value in the valley portion 520-1, and the valley portion 520-1 may be arranged within a depth range where the doping concentration becomes 2 times or less of the local minimum value in the valley portion 220-1.

The valley portion 520-2 of the hydrogen chemical concentration may correspond to the valley portion 220-2 of the doping concentration. The depth position of the valley portion 520-2 may match with the depth position of the valley portion 220-2 while including an error of 10% or less. The valley portion 220-2 may be arranged within a depth range where the hydrogen chemical concentration becomes 2 times or less of the local minimum value in the valley portion 520-2, and the valley portion 520-2 may be arranged within a depth range where the doping concentration becomes 2 times or less of the local minimum value in the valley portion 220-2.

The valley portion 520-3 of the hydrogen chemical concentration may correspond to the valley portion 220-3 of the doping concentration. The depth position of the valley portion 520-3 may match with the depth position of the valley portion 220-3 while including an error of 10% or less. The valley portion 220-3 may be arranged within a depth range where the hydrogen chemical concentration becomes 2 times or less of the local minimum value in the valley portion 520-3, and the valley portion 520-3 may be arranged within a depth range where the doping concentration becomes 2 times or less of the local minimum value in the valley portion 220-3.

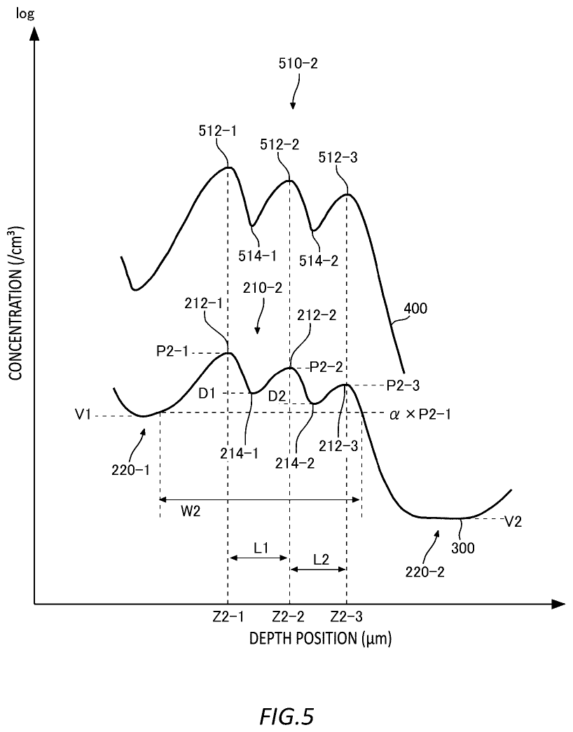

FIG. 5 illustrates a view showing the doping concentration distribution 300 and the hydrogen chemical concentration distribution 400 in the vicinity of the doping concentration peak 210-2. The doping concentration peak 210-2 of this example has a plurality of sub-peaks 212 arranged at different positions in the depth direction. In the example of FIG. 5, the doping concentration peak 210-2 has a sub-peak 212-1, a sub-peak 212-2, and a sub-peak 212-3 in the order of proximity from the lower surface 23 of the semiconductor substrate 10. The sub-peak 212-1 is an example of a first sub-peak closest to the lower surface 23 of the semiconductor substrate 10, the sub-peak 212-2 is an example of a second sub-peak second closest to the lower surface 23, and the sub-peak 212-3 is an example of a third sub-peak third closest to the lower surface. In addition, one recess 214 is arranged between the respective sub-peaks 212. In other words, a recess 214-h in which the doping concentration shows a local minimum value is arranged between a sub-peak 212-h and a sub-peak 212-(h+1) arranged adjacent to each other in the depth direction. Note that h is an integer of 1 or more. h may be 2 or more, 3 or more, or 4 or more.

A maximum value of doping concentrations of the sub-peak 212-h is given as P2-h, and a depth position at which the doping concentration becomes a maximum value P2-h in the sub-peak 212-h is given as Z2-h. The doping concentration P2-2 may be the same as the doping concentration P2-1, or may be smaller than or larger than the doping concentration P2-1. The doping concentration P2-3 may be the same as the doping concentration P2-2, or may be smaller than or larger than the doping concentration P2-2. The doping concentration P2-3 may be the same as the doping concentration P2-1, or may be smaller than or larger than the doping concentration P2-1. In this example, P2-1 >P2-2 >P2-3 is established. In other words, the doping concentrations P2-h of the plurality of sub-peaks 212-h may decrease as distances thereof from the lower surface 23 increase. While the doping concentration P2-1 is a maximum value of the doping concentrations in the doping concentration peak 210-2 in this example, other doping concentrations P2-h may alternatively be a maximum value of the doping concentrations in the doping concentration peak 210-2. The depth position Z2-h corresponds to an implantation position of dopant ions. Further, a minimum value of the doping concentrations in the valley portion 220-k is given as Vk, and a minimum value of the doping concentrations in the recess 214-h is given as Dh.

An interval in the depth direction between the sub-peak 212-h and the sub-peak 212-(h+1) adjacent to each other in the depth direction is given as Lh. The interval Lh is a distance between the depth position Z2-h and the depth position Z2-(h+1).

Each interval Lh may be equal to or smaller than a distance (Z4-Z3) between the doping concentration peak 210-3 and the doping concentration peak 210-4 in the depth direction. A group of the plurality of sub-peaks 212 having the intervals Lh equal to or smaller than the distance (Z4-Z3) may be assumed to be one doping concentration peak 210-2. In this case, the doping concentration Dh of the recess 214 between the respective sub-peaks 212 may be α×P2-max or more, or may be smaller than α×P2-max. The doping concentration P2-max refers to a maximum doping concentration out of the doping concentrations P2-h of the sub-peaks 212-h. A group of the plurality of sub-peaks 212 whose intervals Lh are 0.5 times or less of the distance (Z4-Z3) may be assumed to be one doping concentration peak 210-2, or a group of the plurality of sub-peaks 212 whose intervals Lh are 0.25 times or less of the distance (Z4-Z3) may be assumed to be one doping concentration peak 210-2.

Each interval Lh may be 2 times or less of the full width at half maximum of the doping concentration peak 210-4 shown in FIG. 4 (that is, the peak width W4 in the case of α=0.5). A group of the plurality of sub-peaks 212 whose intervals Lh are 2 times or less of the peak width W4 (note that α=0.5) may be assumed to be one doping concentration peak 210-2. In this case, the doping concentration Dh of the recess 214 between the respective sub-peaks 212 may be α×P2-max or more, or may be smaller than α×P2-max. A group of the plurality of sub-peaks 212 whose intervals Lh are 1.5 times or less of the full width at half maximum of the doping concentration peak 210-4 may be assumed to be one doping concentration peak 210-2, or a group of the plurality of sub-peaks 212 whose intervals Lh are 1 time or less of the full width at half maximum of the doping concentration peak 210-4 may be assumed to be one doping concentration peak 210-2.

As described in FIG. 4, a continuous portion where the doping concentration becomes α×P2-max or more may alternatively be assumed to be one doping concentration peak 210-2. In this case, the doping concentration Dh of the recess 214 between the respective sub-peaks 212 is α×P2-max or more. The interval Lh in this case may be equal to or smaller than the distance (Z4-Z3), or may be larger than the distance (Z4-Z3). The interval Lh may be equal to or smaller than the full width at half maximum of the doping concentration peak 210-4, or may be larger than the full width at half maximum of the doping concentration peak 210-4. Moreover, a range that includes the plurality of sub-peaks 212 whose intervals Lh are equal to or smaller than the distance (Z4-Z3) and where the doping concentration Dh of each of the recesses 214 between the respective sub-peaks 212 is α×P2-max or more may be assumed to be the doping concentration peak 210-2. Further, a range that includes the plurality of sub-peaks 212 whose intervals Lh are equal to or smaller than the peak width W4 (note that α=0.5) and where the doping concentration Dh of each of the recesses 214 between the respective sub-peaks 212 is α×P2-max or more may be assumed to be the doping concentration peak 210-2.

Each interval Lh may be smaller than a distance between the sub-peak 212-1 and the doping concentration peak 210-1 (for example, Z2-Z1 in FIG. 4). Each interval Lh may be 0.5 times or less or 0.25 times or less of the distance (Z2-Z1).

Each interval Lh may be smaller than a distance between the sub-peak 212-3 and the doping concentration peak 210-3 (for example, Z3-(Z2-3) in FIGS. 4 and 5). Each interval Lh may be 0.5 times or less or 0.25 times or less of the distance (Z3-(Z2-3)).

Each interval Lh may be 2 times or less, 1.5 times or less, or 1 time or less of the full width at half maximum of the doping concentration peak 210-3. Each interval Lh may be 2 times or less, 1.5 times or less, or 1 time or less of the full width at half maximum of the doping concentration peak 210-1. Further, each interval Lh may be 1 μm or more, 2 μm or more, 3 μm or more, or 4 μm or more so that the sub-peaks 212 do not overlap with one another.

The doping concentration Dh of at least one recess 214-h may be larger than 0.1 times, larger than 0.2 times, or larger than 0.5 times the maximum value P2-max of the doping concentration of the plurality of sub-peaks 212. Accordingly, a shape of the doping concentration distribution of the doping concentration peak 210-2 can be flattened more, and a maximum value of the doping concentrations of the doping concentration peak 210-2 can be made small. The doping concentration Dh of all the recesses 214-h may be larger than 0.1 times, larger than 0.2 times, or larger than 0.5 times the maximum value P2-max of the doping concentration of the plurality of sub-peaks 212.

The doping concentration Dh of at least one recess 214-h may be larger than 0.1 times, larger than 0.2 times, or larger than 0.5 times the doping concentration P2-h of the adjacent sub-peak 212-h. The doping concentration Dh of all the recesses 214-h may be larger than 0.1 times, larger than 0.2 times, or larger than 0.5 times the doping concentration P2-h of the adjacent sub-peak 212-h.

The doping concentration Dh of at least one recess 214-h may be higher than the doping concentration V1 of the valley portion 220-1. The doping concentration Dh of at least one recess 214-h may be 1.5 times or more, 2 times or more, or 5 times or more of the doping concentration V1. The doping concentration Dh of all the recesses 214-h may be higher than the doping concentration V1 of the valley portion 220-1, or may be 1.5 times or more, 2 times or more, or 5 times or more of the doping concentration V1. By increasing the doping concentration Dh of the recess 214, the maximum doping concentration P2 in the doping concentration peak 210-2 can be made small while maintaining the integrated value of the doping concentrations in the doping concentration peak 210-2. The doping concentration Dh of each recess 214-h may be 10 times or less, 8 times or less, or 6 times or less of the doping concentration V1.

The doping concentration Dh of at least one recess 214-h may be higher than the doping concentration V2 of the valley portion 220-2. The doping concentration Dh of at least one recess 214-h may be 1.5 times or more, 2 times or more, 5 times or more, or 10 times or more of the doping concentration V2. The doping concentration Dh of all the recesses 214-h may be higher than the doping concentration V2 of the valley portion 220-2, or may be 1.5 times or more, 2 times or more, 5 times or more, or 10 times or more of the doping concentration V2. By increasing the doping concentration Dh of the recess 214, the maximum doping concentration P2 in the doping concentration peak 210-2 can be made small while maintaining the integrated value of the doping concentrations in the doping concentration peak 210-2. The doping concentration Dh of each recess 214-h may be 10 times or less, 8 times or less, or 6 times or less of the doping concentration V2.

The doping concentration Dh of at least one recess 214-h may be higher than the doping concentration V3 of the valley portion 220-3 as the deepest valley portion. The doping concentration Dh of at least one recess 214-h may be 1.5 times or more, 2 times or more, 5 times or more, or 10 times or more of the doping concentration V3. The doping concentration Dh of all the recesses 214-h may be higher than the doping concentration V3 of the valley portion 220-3, or may be 1.5 times or more, 2 times or more, 5 times or more, or 10 times or more of the doping concentration V3. By increasing the doping concentration Dh of the recess 214, the maximum doping concentration P2 in the doping concentration peak 210-2 can be made small while maintaining the integrated value of the doping concentrations in the doping concentration peak 210-2. The doping concentration Dh of each recess 214-h may be 10 times or less, 8 times or less, or 6 times or less of the doping concentration V3.

The hydrogen chemical concentration distribution 400 may have a hydrogen sub-peak 512-h corresponding to the sub-peak 212-h of the doping concentration. The hydrogen chemical concentration distribution 400 may have a recess 514-h corresponding to the recess 214-h of the doping concentration.

A depth position of the hydrogen sub-peak 512-h may match with the depth position Z2-h of the sub-peak 212-h of the doping concentration while including an error of 10% or less. A local maximum of the sub-peak 212-h may be arranged within a depth range of a full width at half maximum of the hydrogen sub-peak 512-h, and a local maximum of the hydrogen sub-peak 512-h may be arranged within a depth range of the full width at half maximum of the sub-peak 212-h.

The depth position of the recess 514-h of the hydrogen chemical concentration may match with the depth position of the recess 214-h of the doping concentration while including an error of 10% or less. In the present specification, the depth position of the recess is a position at which the recess shows a local minimum value. When a flat portion in which a portion showing a local minimum value is continuous in the depth direction exists in the recess, the depth position of the recess is a center position of the flat portion in the depth direction. The recess 214-h may be arranged within a depth range where the hydrogen chemical concentration becomes 2 times or less of the local minimum value in the recess 514-h, and the recess 514-h may be arranged within a depth range where the doping concentration becomes 2 times or less of the local minimum value in the recess 214-h.

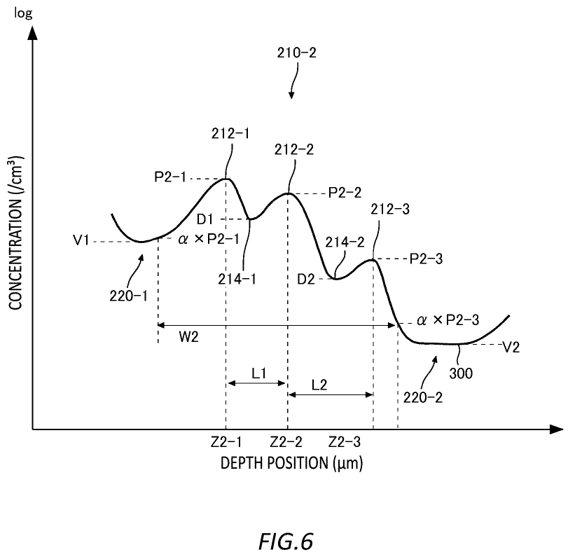

FIG. 6 illustrates a view showing another example of the doping concentration distribution in the vicinity of the doping concentration peak 210-2. Regarding the doping concentration peak 210-2 of this example, the doping concentration distribution of the sub-peak 212-3 differs from that of the example shown in FIG. 5. Other portions are similar to those of the example shown in FIG. 5.

In this example, a ratio (P2-3)/(P2-2) of the doping concentration P2-3 of the sub-peak 212-3 to the doping concentration P2-2 of the sub-peak 212-2 is smaller than a ratio (P2-2)/(P2-1) of the doping concentration P2-2 of the sub-peak 212-2 to the doping concentration P2-1 of the sub-peak 212-1. For example, the doping concentration P2-2 may be 75% to 100% of the doping concentration P2-1, and the doping concentration P2-3 may be 25% to 50% of the doping concentration P2-2. By setting the doping concentration P2-3 as an intermediate concentration between the doping concentration P2-2 and the doping concentration V2 of the valley portion 220-2, a gradient of a slope of the doping concentration peak 210-2 on the upper surface 21 side can be made gradual. Accordingly, the voltage overshoot when the space charge region reaches the slope can be suppressed.

The doping concentration P2-3 of the sub-peak 212-3 may be lower than α×P2-1. Note that a distance L2 between the sub-peak 212-3 and the sub-peak 212-2 is equal to or smaller than the full width at half maximum of the doping concentration peak 210-4. In this example, an end portion of the doping concentration peak 210-2 on the lower surface 23 side is a point at which the doping concentration becomes α×P2-1 for the first time on a side closer to the lower surface 23 than the local maximum of the sub-peak 212-1. Moreover, an end portion of the doping concentration peak 210-2 on the upper surface 21 side is a point at which the doping concentration becomes α×P2-3 for the first time on a side closer to the upper surface 21 than the local maximum of the sub-peak 212-3.

The distance L2 between the sub-peak 212-2 and the sub-peak 212-3 may be larger than the distance L1 between the sub-peak 212-1 and the sub-peak 212-2. The distance L2 may be 1.2 times or more, 1.5 times or more, or 2 times or more of the distance L1. Note that the distance L2 is equal to or smaller than the full width at half maximum of the doping concentration peak 210-4. Even with such a configuration, a gradient of a slope of the doping concentration peak 210-2 on the upper surface 21 side can be made gradual. Accordingly, the voltage overshoot when the space charge region reaches the slope can be suppressed.

The number of sub-peaks 212 included in the doping concentration peak 210-2 may be four or less. If the number of sub-peaks 212 becomes too large, the width of the doping concentration peak 210-2 in the depth direction may become too large to thus reach the doping concentration peak 210-3. Moreover, if the sub-peaks 212 are congested in a narrow range in the depth direction, the sub-peaks 212 overlap one another, and the maximum value of the doping concentrations becomes large.

The peak width W2 of the second peak may be 5 times or less of the peak width W4 of the doping concentration peak 210-4. If the peak width W2 becomes too large, the doping concentration peak 210-2 may reach the doping concentration peak 210-3. The peak width W2 may be 4 times or less of the peak width W4. The peak width W2 may be 5 times or less or 4 times or less of the peak width W1. The peak width W2 may be 5 times or less or 4 times or less of the peak width W3.

The peak width W2 of the second peak may be 0.5 times or less of the distance (Z4-Z1) between the doping concentration peak 210-1 and the doping concentration peak 210-4. If the peak width W2 becomes too large, the doping concentration peak 210-2 may reach the doping concentration peak 210-3. The peak width W2 may be 0.4 times or less, 0.3 times or less, or 0.2 times or less of the distance (Z4-Z1).

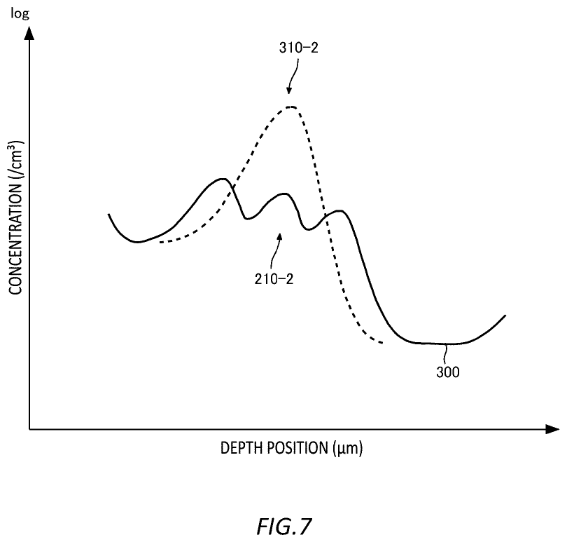

FIG. 7 illustrates a view showing a doping concentration distribution of a doping concentration peak 310-2 according to a comparative example. A semiconductor device according to the comparative example has the doping concentration peak 310-2 in place of the doping concentration peak 210-2 in the configuration of the semiconductor device 100 described in FIGS. 1 to 6. Other structures are similar to those of the semiconductor device 100.

The doping concentration peak 310-2 has a single concentration peak. In other words, the doping concentration peak 310-2 does not have the plurality of sub-peaks 212. The peak width of the doping concentration peak 310-2 is smaller than the peak width of the doping concentration peak 210-2. The doping concentration peak 310-2 is formed by implanting dopant ions at a single depth position. A dose amount of the dopant ions with respect to the doping concentration peak 310-2 is substantially the same as the total dose amount of the dopant ions with respect to the doping concentration peak 210-2. In other words, the doping concentration peak 210-2 is obtained by dividing the dose amount of the dopant ions with respect to the doping concentration peak 310-2 by the plurality of depth positions, and implanting the dopant ions at the respective depth positions.

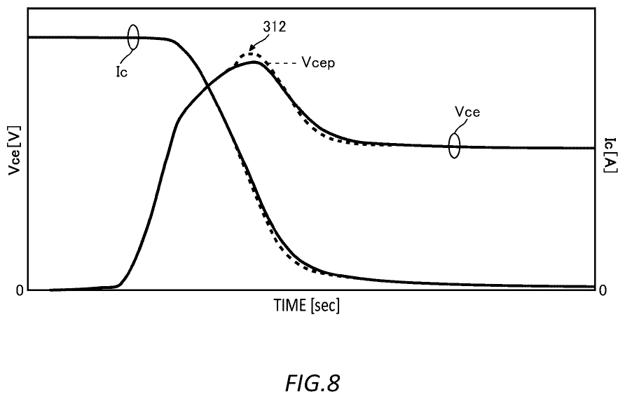

FIG. 8 shows a voltage waveform and a current waveform during turn-off of a semiconductor device according to an example and a comparative example. The horizontal axis in FIG. 8 represents time, and the vertical axes respectively represent the collector-emitter voltage Vce and a collector current Ic. In FIG. 8, waveforms of the comparative example having the doping concentration peak 310-2 shown in FIG. 7 are indicated by broken lines, and waveforms of the example having the doping concentration peak 210-2 are indicated by solid lines.

As indicated by the broken line in FIG. 8, a surge portion 312 is generated in the voltage waveform during turn-off in the comparative example. This is considered to be because the space charge region during turn-off has reached the doping concentration peak 310-2 having a high concentration. In contrast, in the example indicated by the solid line in FIG. 8, it has been possible to suppress the surge portion 312. This is considered to be because the maximum value of the doping concentrations of the doping concentration peak 210-2 has been suppressed. Further, portions of the voltage waveform and the current waveform other than the surge portion 312 are substantially equivalent between the comparative example and the example. Thus, it can be seen that in the semiconductor device 100 according to the example, occurrence of a voltage overshoot can be suppressed while hardly causing any influence on the voltage characteristics and current characteristics. According to the semiconductor device 100, it is possible to suppress a voltage overshoot during turn-off and perform a switching operation at a higher speed.

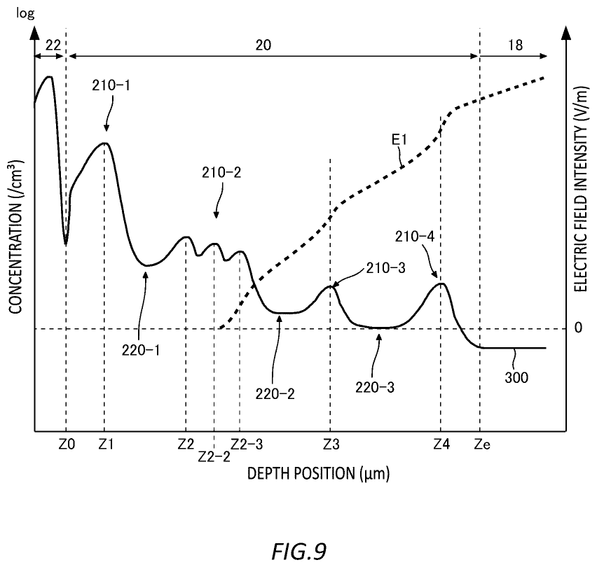

FIG. 9 illustrates a view showing a distribution example of an electric field intensity E1 during turn-off. The electric field intensity E1 is an electric field intensity obtained when the collector-emitter voltage Vce is a predetermined clamp voltage Vcep. The clamp voltage Vcep of this example is a maximum value of the collector-emitter voltage Vce during turn-off as shown in FIG. 8.

As shown in FIG. 9, the electric field intensity E1 at a time when the clamp voltage Vcep is applied becomes substantially 0 in the vicinity of the slope of the doping concentration peak 210-2 on the upper surface 21 side. In other words, when the clamp voltage Vcep is applied, the space charge region reaches the slope of the doping concentration peak 210-2 on the upper surface 21 side. Thus, if the gradient of the slope and the doping concentration of the doping concentration peak 210-2 are large, the voltage overshoot during turn-off becomes large. In this example, the peak width of the doping concentration peak 210-2 is set large, and the maximum value of the doping concentrations is set small. Accordingly, the gradient of the slope and the doping concentration of the doping concentration peak 210-2 can be made small, and thus the voltage overshoot can be suppressed.

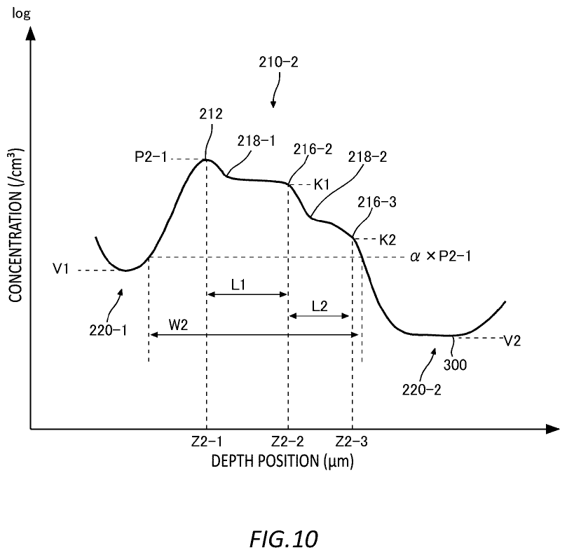

FIG. 10 illustrates a view showing another example of the doping concentration distribution of the doping concentration peak 210-2. Configurations other than the doping concentration peak 210-2 are similar to those of the semiconductor device 100 described in FIGS. 1 to 9.

The doping concentration peak 210-2 of this example has one or more sub-peaks 212 and one or more kink portions 216. The doping concentration peak 210-2 of this example is also formed by implanting dopant ions at the plurality of depth positions. Even in this case, the recess 214 in which the doping concentration shows a local minimum value may not be observed between the implantation positions of the dopant ions in the doping concentration distribution. In addition, the sub-peak 212 in which the doping concentration shows a local maximum value may not be observed at the implantation positions of the dopant ions.

When the horizontal axis represents the depth position and the vertical axis represents the doping concentration, the doping concentration distribution of the doping concentration peak 210-2 in this example has one or more concave portions 218 in which the distribution curve becomes a downwardly convex shape and one or more kink portions 216 in which the distribution curve becomes an upwardly convex shape. The concave portion 218-h may be arranged at the same depth position as the recess 214-h described in FIGS. 1 to 9. The concave portion 218-h may have the same doping concentration as the recess 214-h described in FIGS. 1 to 9.

The kink portion 216 corresponds to the sub-peak 212 described in FIGS. 1 to 9. When the kink portion 216 is arranged closer to the upper surface 21 than one sub-peak 212, the sub-peak 212 corresponds to the sub-peak 212-1, and the kink portion 216-h corresponds to the sub-peak 212-h (note that h is an integer of 2 or more). When the kink portion 216 is arranged closer to the lower surface 23 than one sub-peak 212, the kink portion 216-h corresponds to the sub-peak 212-h (note that h is an integer of 1 or more), and the sub-peak 212 corresponds to the sub-peak 212-4. The kink portion 216 may be arranged at the same depth position as the corresponding sub-peak 212 described in FIGS. 1 to 9. The kink portion 216 may have the same doping concentration as the corresponding sub-peak 212 described in FIGS. 1 to 9.

In FIG. 10, the concave portion 218 and the kink portion 216 are alternately arranged on a side closer to the upper surface 21 than one sub-peak 212. The concave portion 218 in this case has a downwardly convex shape in the graph, in which the doping concentration continuously decreases from the lower surface 23 toward the upper surface 21 without showing the local minimum value. Further, the kink portion 216 has an upwardly convex shape in the graph, in which the doping concentration continuously decreases from the lower surface 23 toward the upper surface 21 without showing the local maximum value.

In another example, the concave portion 218 and the kink portion 216 may be alternately arranged on a side closer to the lower surface 23 than one sub-peak 212. The kink portion 216 in this case has an upwardly convex shape in the graph, in which the doping concentration continuously increases from the lower surface 23 toward the upper surface 21 without showing the local maximum value. Further, the concave portion 218 has a downwardly convex shape in the graph, in which the doping concentration continuously increases from the lower surface 23 toward the upper surface 21 without showing the local minimum value.

In another example, the concave portion 218 and the kink portion 216 may be arranged between one sub-peak 212 and the lower surface 23 and also between the sub-peak 212 and the upper surface 21. Alternatively, the concave portion 218 and the kink portion 216 may be arranged between two sub-peaks 212. Alternatively, the concave portion 218 and the kink portion 216 may be arranged between two recesses 214.

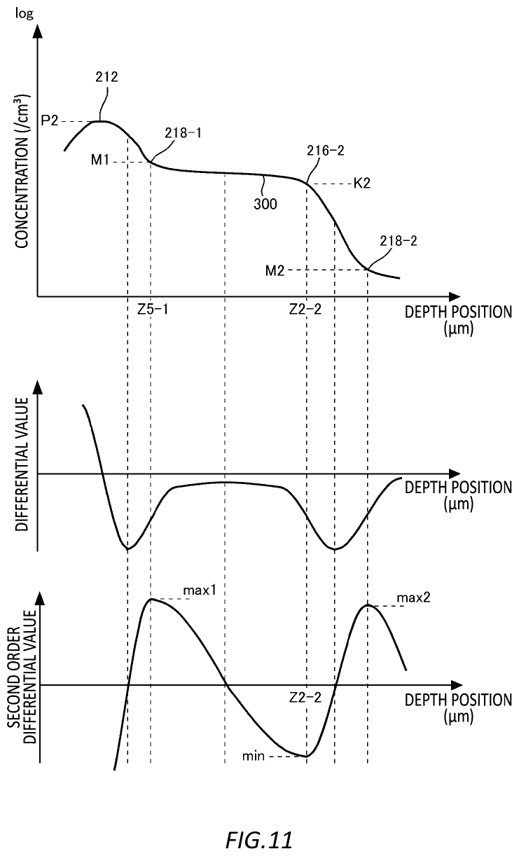

FIG. 11 illustrates a view for describing the depth positions of the concave portion 218 and the kink portion 216. FIG. 11 shows a doping concentration distribution, a differential value obtained based on the depth position in the doping concentration, and a second order differential value obtained based on the depth position in the doping concentration. The concave portion 218-h may be a point of a depth position Z5-h at which the doping concentration distribution does not show a local minimum value and a second order differential value of the doping concentration becomes a local maximum value maxh. In this example, the concave portion 218-1 and the concave portion 218-2 are present. The doping concentration at the depth position Z5-h may be used as a doping concentration Mh of the concave portion 218-h. The kink portion 216-h may be a point of a depth position Z2-h at which the doping concentration distribution does not show a local maximum value and the second order differential value of the doping concentration becomes a local minimum value min. In this example, one kink portion 216-2 is present. The doping concentration at the depth position Z2-h may be used as a doping concentration Kh of the kink portion 216-h.

The doping concentration Kh of at least one kink portion 216-h may be 0.1 times or more of the maximum value P2 in a range in which it does not exceed the maximum value P2 of the doping concentrations of the one or more sub-peaks 212. The doping concentration Kh may be 0.2 times or more or 0.5 times or more of the doping concentration P2. The doping concentration Kh of all the kink portions 216-h may be 0.1 times or more, 0.2 times or more, or 0.5 times or more of the maximum value P2 in a range in which it does not exceed the maximum value P2. The doping concentration Kh may be equal to or smaller than the maximum value P2. The doping concentration Kh of each kink portion 216-h may be 0.1 times or more, 0.2 times or more, or 0.5 times or more of a doping concentration Kh−1 of a kink portion 216-(h−1) one before that. The doping concentration Kh of each kink portion 216-h may be 0.1 times or more, 0.2 times or more, or 0.5 times or more of a doping concentration Mh of the concave portion 218-h adjacent thereto on the lower surface 23 side.

The doping concentration Kh of at least one kink portion 216-h may be higher than the doping concentration V1 of the valley portion 220-1. The doping concentration Kh may be 2 times or more, 5 times or more, or 10 times or more of the doping concentration V1. The doping concentration Kh of all the kink portions 216-h may be larger than the doping concentration V1, or may be 2 times or more, 3 times or more, or 5 times or more of the doping concentration V1. The doping concentration Kh may be 10 times or less or 6 times or less of the doping concentration V1. The doping concentration Kh of at least one kink portion 216-h may be 2 times or more of the doping concentration V3 of the valley portion 220-3. The doping concentration Kh may be 3 times or more or 5 times or more of the doping concentration V3. The doping concentration Kh of all the kink portions 216-h may be 2 times or more, 3 times or more, or 5 times or more of the doping concentration V3. The doping concentration Kh may be 10 times or less or 6 times or less of the doping concentration V3.

While the present invention has been described by way of the embodiments, the technical scope of the present invention is not limited to the above described embodiments. It is apparent to persons skilled in the art that various alterations or improvements can be made to the above described embodiments. It is also apparent from the description of the claims that embodiments added with such alterations or improvements can be included in the technical scope of the present invention.

The operations, procedures, steps, and stages of each process performed by a device, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A semiconductor device, comprising:
a semiconductor substrate which has an upper surface and a lower surface and is provided with a drift region of a first conductivity type; and
a buffer region of a first conductivity type, which is provided between the lower surface of the semiconductor substrate and the drift region, has three or more doping concentration peaks in a depth direction of the semiconductor substrate, and has a higher concentration than the drift region, wherein
the three or more doping concentration peaks include a deepest peak farthest from the lower surface of the semiconductor substrate and a second peak second closest to the lower surface of the semiconductor substrate, and
a peak width of the second peak is 2 times or more of a peak width of the deepest peak in the depth direction.

2. The semiconductor device according to claim 1, wherein
the second peak includes a plurality of sub-peaks in the depth direction,
the three or more doping concentration peaks include a second deepest peak whose distance from the lower surface of the semiconductor substrate is second largest, and
an interval between two of the sub-peaks adjacent to each other in the depth direction is smaller than a distance between the second deepest peak and the deepest peak.

3. The semiconductor device according to claim 1, wherein
the second peak includes a plurality of sub-peaks in the depth direction, and
an interval between two of the sub-peaks adjacent to each other in the depth direction is 2 times or less of a full width at half maximum of the deepest peak.

4. The semiconductor device according to claim 2, wherein
a distribution of a doping concentration of the second peak in the depth direction has a plurality of recesses, and the recesses are each arranged between the respective sub-peaks, and
the doping concentration of at least one of the recesses is larger than 0.1 times a maximum value of the doping concentration of the plurality of sub-peaks.

5. The semiconductor device according to claim 4, wherein
a distribution of the doping concentration of the buffer region in the depth direction has a plurality of valley portions, and the valley portions are each arranged between the respective doping concentration peaks,
the plurality of valley portions include a first valley portion closest to the lower surface of the semiconductor substrate, and
the doping concentration of at least one of the recesses is higher than the doping concentration of the first valley portion.

6. The semiconductor device according to claim 4, wherein
a distribution of the doping concentration of the buffer region in the depth direction has a plurality of valley portions, and the valley portions are each arranged between the respective doping concentration peaks,
the plurality of valley portions include a deepest valley portion closest to the upper surface of the semiconductor substrate, and
the doping concentration of at least one of the recesses is 2 times or more of the doping concentration of the deepest valley portion.

7. The semiconductor device according to claim 2, wherein
the plurality of sub-peaks include a first sub-peak closest to the lower surface of the semiconductor substrate, a second sub-peak second closest to the lower surface, and a third sub-peak which is third closest to the lower surface and has a lower concentration than the second sub-peak, and
a ratio of a doping concentration of the third sub-peak to the doping concentration of the second sub-peak is smaller than a ratio of the doping concentration of the second sub-peak to the doping concentration of the first sub-peak.

8. The semiconductor device according to claim 2, wherein
the plurality of sub-peaks include a first sub-peak closest to the lower surface of the semiconductor substrate, a second sub-peak second closest to the lower surface, and a third sub-peak which is third closest to the lower surface and has a lower concentration than the second sub-peak, and
a distance between the second sub-peak and the third sub-peak in the depth direction is larger than a distance between the first sub-peak and the second sub-peak in the depth direction.

9. The semiconductor device according to claim 2, wherein
the three or more doping concentration peaks include a first peak closest to the lower surface of the semiconductor substrate,
the plurality of sub-peaks include a first sub-peak closest to the lower surface of the semiconductor substrate, and
the interval between two of the sub-peaks adjacent to each other in the depth direction is smaller than a distance between the first peak and the first sub-peak.

10. The semiconductor device according to claim 2, wherein
a number of the sub-peaks in the second peak is four or less.

11. The semiconductor device according to claim 1, wherein
a distribution of a doping concentration of the second peak in the depth direction has one or more sub-peaks and one or more kink portions.

12. The semiconductor device according to claim 11, wherein
the doping concentration of at least one of the kink portions is 0.1 times or more of a maximum value of the doping concentration of the one or more sub-peaks.

13. The semiconductor device according to claim 11, wherein
a distribution of the doping concentration of the buffer region in the depth direction has a plurality of valley portions, and the valley portions are each arranged between the respective doping concentration peaks,
the plurality of valley portions include a first valley portion closest to the lower surface of the semiconductor substrate, and
the doping concentration of at least one of the kink portions is higher than the doping concentration of the first valley portion.

14. The semiconductor device according to claim 11, wherein
a distribution of the doping concentration of the buffer region in the depth direction has a plurality of valley portions, and the valley portions are each arranged between the respective doping concentration peaks,
the plurality of valley portions include a deepest valley portion closest to the upper surface of the semiconductor substrate, and
the doping concentration of at least one of the kink portions is 2 times or more of the doping concentration of the deepest valley portion.

15. The semiconductor device according to claim 1, wherein
the three or more doping concentration peaks include a first peak closest to the lower surface of the semiconductor substrate and a third peak third closest to the lower surface of the semiconductor substrate, and
a doping concentration of the second peak is lower than the doping concentration of the first peak and higher than the doping concentration of the third peak.

16. The semiconductor device according to claim 1, wherein
the peak width of the second peak is 5 times or less of the peak width of the deepest peak.

17. The semiconductor device according to claim 1, wherein
the three or more doping concentration peaks include a first peak closest to the lower surface of the semiconductor substrate, and
the peak width of the second peak is 0.5 times or less of a distance between the first peak and the deepest peak in the depth direction.

18. The semiconductor device according to claim 3, wherein
a distribution of a doping concentration of the second peak in the depth direction has a plurality of recesses, and the recesses are each arranged between the respective sub-peaks, and
the doping concentration of at least one of the recesses is larger than 0.1 times a maximum value of the doping concentration of the plurality of sub-peaks.

19. The semiconductor device according to claim 3, wherein
the plurality of sub-peaks include a first sub-peak closest to the lower surface of the semiconductor substrate, a second sub-peak second closest to the lower surface, and a third sub-peak which is third closest to the lower surface and has a lower concentration than the second sub-peak, and
a ratio of a doping concentration of the third sub-peak to the doping concentration of the second sub-peak is smaller than a ratio of the doping concentration of the second sub-peak to the doping concentration of the first sub-peak.

20. The semiconductor device according to claim 3, wherein
the plurality of sub-peaks include a first sub-peak closest to the lower surface of the semiconductor substrate, a second sub-peak second closest to the lower surface, and a third sub-peak which is third closest to the lower surface and has a lower concentration than the second sub-peak, and
a distance between the second sub-peak and the third sub-peak in the depth direction is larger than a distance between the first sub-peak and the second sub-peak in the depth direction.
